(19) United States
(12) Patent Application Publication
(10) Pub. No.: US 2025/0104996 A1
(43) Pub. Date: Mar. 27, 2025

(54) TUNABLE ELECTRON TRANSPARENT SUBSTRATES FOR HIGH-RESOLUTION CHARACTERIZATION

(71) Applicant: MATTIQ, INC., Skokie, IL (US)

(72) Inventors: Andrey IVANKIN, Skokie, IL (US); Jordan H. SWISHER, Skokie, IL (US); Carolin B. WAHL, Skokie, IL (US)

(21) Appl. No.: 18/892,369

(22) Filed: Sep. 21, 2024

Related U.S. Application Data
(60) Provisional application No. 63/539,922, filed on Sep. 22, 2023.

(51) Int. Cl. H01L 21/02; H01L 21/66; H01L 21/78

(52) U.S. Cl. CPC H01L 21/02016; H01L 21/02019; H01L 21/02021; H01L 21/02697; H01L 21/78; H01L 22/12

(57) ABSTRACT

Devices, systems, and methods for electron transparent substrates can include electron transparent windows comprising thin film. Trenches can be defined for sectioning areas, and further sub-areas. Different trench characteristics can permit desirable cleaving by areas, and further by sub-areas to support ease of use.

### CROSS-REFERENCE

This U.S. utility application claims the benefit of priority to U.S. provisional application No. 63/539,922, filed on Sep. 22, 2023, entitled “TUNABLE ELECTRON TRANSPARENT SUBSTRATES FOR HIGH-RESOLUTION CHARACTERIZATION,” the contents of which are hereby incorporated by reference in their entirety.

### FIELD

The present disclosure concerns devices, systems, and methods for substrates. More specifically, the present disclosure concerns devices, systems, and methods for nanoscale substrate features.

### SUMMARY

According to an aspect of the present disclosure, a method for preparing electron transparent substrate may include providing a base wafer having a bulk core, a first thin film layer disposed on one side of the bulk core corresponding with a frontside of the base wafer, and a second thin film layer disposed on an opposite side of the bulk core corresponding with a backside of the base wafer; subjecting the base wafer, on the backside, to (i) photolithography to define removal regions, and to (ii) etching to remove portions of the second thin film layer corresponding to the defined removal regions to allow exposure of bulk core via the backside of the base wafer; and subjecting the base wafer, on the backside, to wet etching to remove portions of the bulk core, wherein removed portions of the bulk core include thickened portions of the bulk core extending through the bulk core to the first thin film layer to expose portions of the first thin film layer via the backside to define electron transparent windows, and trench portions extending partially into the bulk core from the backside to define trenches for sectioning of the base wafer.

In some embodiments, the method may further include subjecting the base wafer to dry etching for thickness reduction of the first thin film layer. Subjecting the base wafer to dry etching for thickness reduction of the first thin film layer may include thickness reduction of the first thin film layer in regions including the electron transport windows. Subjecting the base wafer to dry etching may include reactive plasma etching.

In some embodiments, subjecting the base wafer to wet etching to remove trench portions may include partially removing portion of the bulk core as the trench portions such that the defined trenches do not extend entirely through the bulk core to the first thin film layer. In some embodiments, the method may further include cleaving the wafer into samples according to sectioning as defined by the trenches.

In some embodiments, sectioning may include sample sectioning the base wafer into sample sections and sub-sectioning the sample sections into sub-sample sections. Cleaving may includes cleaving the base wafer into samples according to the sample sections and sub-cleaving the samples into sub-samples according to the sub-sample sections.

In some embodiments, the method may further include determining mechanical stability parameters for sectioning based on determined mechanical stability needs. Sectioning based on the determined mechanical stability needs may include defining trench dimensions for samples as greater than trench dimensions for sub-samples.

In some embodiments, the method may further include modifying the base wafer. Modifying the base wafer may include one or more of atomic layer deposition of thin films, chemical vapor deposition of surface modifiers, spin-coating with polymeric or thin films. Modifying the base wafer includes depositing conductive material near substrate edges. Modifying may be performed before subjecting the base wafer, on the backside, to photolithography.

In some embodiments, modifying may be performed after subjecting the base wafer, on the backside, to photolithography, and before subjecting the base wafer, on the backside, to wet etching. In some embodiments, the method may further include frontside processing.

According to another aspect of the present disclosure, a substrate may include a bulk core and a thin film layer deposited in part on said bulk portion, the thin film layer including a plurality of electron transport windows. Each window may include the thin film layer material exposed on a frontside and exposed on a backside through removed portions of the bulk core. The substrate may further include sectioning according to trenches defined by trenched portions of removed bulk core extending partially into the bulk core from the backside.

In some embodiments, the trenches may define an outer perimeter of a plurality of chip areas. Each chip area may include a plurality of windows. The trenches may be configured for cleaving to detach the chip areas from each other.

According to another aspect of the present disclosure, a wafer may include a bulk portion and a thin film layer disposed on the bulk portion, a plurality of first trenches forming the boundaries of a plurality of substrate areas. Each substrate area may include a plurality of electron transparent windows defined therein. Each electron transparent window may include the thin film layer accessible from opposite sides of the wafer. The first trenches may be configured be cleaved to form substrate samples defined by the substrate areas.

In some embodiments, an edge length of one or more of the substrate areas may be within the range of 0.3 to 15 cm. In some embodiments, the wafer may further include a plurality of second trenches. The second trenches may form the outer perimeter of a plurality of chip areas within each substrate area. Each chip area may include a plurality of the electron transparent windows. The second trenches may be configured to be cleaved to form chips defined by the chip areas.

In some embodiments, a width of one or more of the first trenches may be greater than a width of one or more of the second trenches. The plurality of chips areas may include 0 to 1500 chips areas. An edge length of at least one of the chip areas may be within the range of 2 to 150 mm. Each chip may be uniquely labeled. For example, frontside photolithography may be applied to result in each substrate and/or each chip having a unique label, such as an identifying number.

In some embodiments, the electron transparent windows may have a thickness within the range of 1 to 100 nm. The electron transparent windows may have at least one minimum dimension within the range of 1 to 200 μm within a longitudinal-lateral plane of the wafer. The electron transparent windows may be spaced apart from each other by a distance within the range of 1 to 10000 μm within a longitudinal-lateral plane of the wafer

In some embodiments, the electron transparent windows may include more than two windows each spaced apart from adjacent windows by the same distance within a longitudinal-lateral plane of the wafer. The bulk portion may include Silicon (Si). The bulk portion may be within the range of 50 to 3000 μm thick. In some embodiments, the thin film layer comprises Silicon Nitride (SiNx). The thin film layer is within the range of 1 to 1000 nm thick.

According to an aspect of the present disclosure, a method for preparing electron transparent substrate of tunable design may include providing a silicon (Si) blank; determining a transparent window parameter; determining a sectioning parameter; subjecting the blank to photolithography, dry etching on a backside of the blank to remove SiNₓ for exposure of Si; and subjecting the blank to wet etching to provide electron-transparent windows comprising free-standing SiNₓ, wherein the electron transparent windows are defined with the determined transparent window parameter; and sectioning the blank according to the determined sectioning parameter.

In some embodiments, determining the transparent window parameter may include determining at least one of width of transparent window, length of transparent window, thickness of transparent windows, distance between adjacent transparent windows, quantity of transparent windows, and geometry of arrangement of transparent windows. Determining the sectioning parameter may include determining of zero sectioning such that no sectioning is applied.

In some embodiments, the blank may be a silicon wafer. The silicon wafer includes silicon nitride film. In some embodiments, the method further comprising applying silicon nitride film to the wafer.

In some embodiments, the method may include subjecting the blank to other dry etching for thickness reduction. Subjecting the blank to other dry etching may include reactive plasma etching. In some embodiments, the sectioning may include trenching portions of the blank for easy dicing.

In some embodiments, the method may include dicing the blank into samples according to the sectioning. Sectioning may include sub-sectioning and dicing includes sub-dicing the blank into sub-samples according to the sub-sectioning. In some embodiments, the determining the sectioning parameter may include determining mechanical stability parameters for the samples. In some embodiments, determining the sectioning parameter may include determining the sectioning parameter based on the determined mechanical stability needs. In some embodiments, sectioning based on the sectioning parameter may include sectioning based on the determined mechanical stability needs. Sectioning based on the determined mechanical stability needs including defining trench dimensions for samples greater than trench dimensions for sub-samples.

In some embodiments, determining the transparent window parameter may include determining mechanical stability parameters. In some embodiments, determining the transparent window parameter may include defining the electron transparent windows based on the determined mechanical stability needs.

In some embodiments, determining at least one transparent window parameter includes determining at least one of width of transparent window, length of transparent window, thickness of transparent windows, distance between adjacent transparent windows, quantity of transparent windows, and geometry of arrangement of transparent windows, based on the determined mechanical stability needs. In some embodiments, determining at least one transparent window parameter includes defining the electron transparent windows based on the determined transparent window parameter.

In some embodiments, the method may further include modifying the provided blank. Modifying the provided blank may include one or more of atomic layer deposition of thin films, chemical or physical vapor deposition of surface modifiers, spin-coating with polymeric or thin films. Modifying the provided blank may include depositing conductive material. In some embodiments, modifying may be performed before subjecting the blank to photolithography, dry etching. Modifying may be performed after subjecting the wafer to photolithography, dry etching, and after sectioning the blank for dicing. In some embodiments, the method may include frontside processing.

According to another aspect of the present disclosure, a method for preparing electron transparent substrate tunable design may include providing a silicon (Si) wafer; subjecting the wafer to photolithography, dry etching on a backside of the wafer to remove SiNx for exposure of Si; and subjecting the wafer to wet etching to provide electron transparent windows comprising free-standing SiNx having tuned dimensions. In some embodiments, the method may include subjecting the wafer to other dry etching for thickness reduction. Subjecting the wafer to other dry etching may include reactive plasma etching.

In some embodiments, the method may further include sectioning the wafer for dicing. Sectioning may include trenching portions of the wafer for easy dicing. In some embodiments, the method may include dicing the wafer into samples according to the sectioning. In some embodiments, sectioning may include sub-sectioning. In some embodiments, dicing may include sub-dicing the wafer into sub-samples according to the sub-sectioning.

In some embodiments, the method may further include determining mechanical stability parameters for the samples. In some embodiments, the method may further include sectioning based on the determined mechanical stability needs. Sectioning based on the determined mechanical stability needs may include defining trench dimensions for samples greater than trench dimensions for sub-samples. In some embodiments, the method may further include determining mechanical stability parameters. In some embodiments, the method may further include defining the electron transparent windows based on the determined mechanical stability needs.

In some embodiments, defining the electron transparent windows based on the determined mechanical stability needs may include determining at least one transparent window parameter including at least one of width of transparent window, length of transparent window, thickness of transparent windows, distance between adjacent transparent windows, quantity of transparent windows, and geometry of arrangement of transparent windows, based on the determined mechanical stability needs In some embodiments, defining the electron transparent window may include defining the electron transparent windows based on the determined transparent window parameter.

In some embodiments, the method may include modifying the provided wafer. Modifying the provided wafer may include one or more of atomic layer deposition of thin films, chemical or physical vapor deposition of surface modifiers, spin-coating with polymeric or thin films. Modifying the provided wafer may include depositing conductive material. Modifying may be performed before subjecting the wafer to photolithography, dry etching. In some embodiments, modifying may be performed after subjecting the wafer to photolithography, dry etching, and after sectioning the wafer for dicing. In some embodiments, the method may include frontside processing.

According to another aspect of the present disclosure, a method for preparing a nanomaterial library for high-resolution characterization may include providing a silicon (Si) wafer; subjecting the wafer to photolithography, dry etching on a backside of the wafer to remove SiNx for exposure of Si; and subjecting the wafer to wet etching to provide electron transparent windows comprising free-standing SiNx having tuned dimensions. In some embodiments, the method may further include depositing nanomaterials onto the substrate to define the library for high-resolution characterization.

### BRIEF DESCRIPTION

The detailed description particularly refers to the accompanying figures in which:

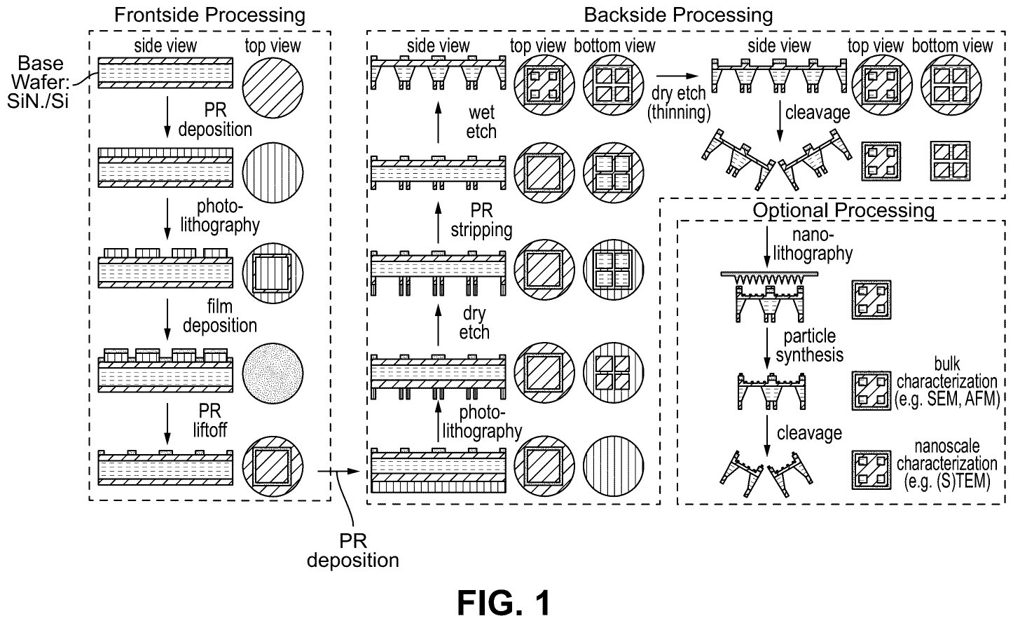

FIG. 1 is a schematic illustration indicating processing to prepare a substrate and the features of the resulting substrate, in accordance with disclosed embodiments; and

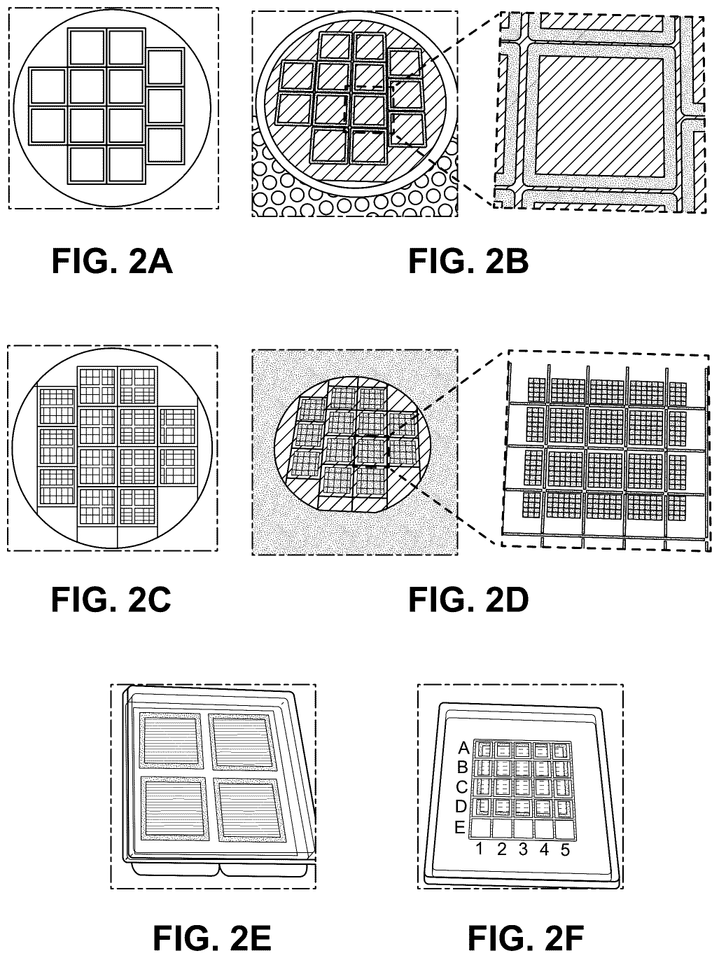

FIG. 2A-2F are examples of a flow of substrate fabrication, including wafer processing, substrates produced from the larger wafer, and a substrate sectioned into smaller chips.

### DETAILED DESCRIPTION

Commercial substrates for (scanning) transmission electron microscopy ((S)TEM) come in small, e.g., 3.05 mm diameter, chips. This small size parameter can present significant challenges. For example, one possible technique may include fabricating micro- and nanostructured materials, features, and/or devices onto the electron transparent substrates compatible with high-resolution structural characterization techniques (i.e., (S)TEM, energy-dispersive X-ray spectroscopy (EDS), etc.). However, these approaches can have low throughput, and may be incompatible or inconvenient to use with other characterization techniques, for example, those that require larger-area samples or more material, e.g., optical microscopy, infrared or Raman spectroscopy, x-ray diffractometry or spectroscopy, secondary ion mass spectrometry, and others. Micro- and nanostructured entities can be fabricated with higher throughput over chips having larger area, to provide compatibility with a wider range of characterization techniques. But these approaches may be incompatible with the high-resolution structural characterization techniques.

One example of such challenges is when libraries of nanomaterials are fabricated over square centimeter-scale chips via polymer pen lithography (PPL), ink-jet printing, sputter coating, electrodeposition or other methods. In such instances, structural characterization of materials within libraries is limited to lower resolution and/or less informative techniques, such as atomic force microscopy (AFM), scanning electron microscopy (SEM), etc. To characterize materials within a library at higher resolution, select materials must be prepared in a separate (oftentimes fundamentally different) experiment at much lower throughput, and then deposited onto a commercial electron transparent substrate. This leads to additional variables in the material synthesis, which may cause the structure analyzed at high-resolution to be fundamentally different than the structure of the material within the library.

Another example is the analysis of thin film materials over large areas. In order to perform defect analysis on such a material, it can be necessary to either transfer it to a compatible substrate, which can introduce additional defects in the process and may fundamentally change the material to be analyzed, or to extract regions of interest from the film using low-throughput and/or expensive techniques such as focused ion beam (FIB) liftouts, introducing selection bias, artifacts, and/or potentially destroying the material in to process.

Another example is the analysis of micro-/nanostructured meso- to macroscale materials and devices with one of the dimensions exceeding the dimensions of the commercial (S)TEM chips. Application-specific performance of these materials and devices can strongly dependent on the local micro- and nanostructure and defects that generally cannot be analyzed on the same substrate without extracting regions of interest from the materials or devices using low-throughput and/or expensive techniques such as focused ion beam (FIB) liftouts, introducing selection bias, artifacts, and/or potentially destroying the material in to process.

Within the present disclosure, devices, systems, and methods are disclosed concerning large-area electron transparent substrates and their fabrication. These substrates can be compatible with a range of micro- and nanofabrication techniques, material library fabrication techniques (e.g., PPL), and/or the highest-resolution characterization techniques available. Devices, systems, and methods within the present disclosure can allow fabrication of material libraries on electron transparent substrates, and/or testing the same materials for their atomic structure and/or application-specific characteristics (catalytic activity, selectivity, durability, corrosion stability, mechanical properties, conductivity, etc.).

Exemplary desired properties of these substrates can include as follows:
≥1 cm² total area;
Periodic electron transparent windows (i.e. portions that are free-standing membranes);
Membranes that are ≤20 nm thick;
Adaptable to high-resolution TEM; and
Mechanically robust to withstand general handling, surface modification (i.e. spin-coating, plasma treatment), high-temperature annealing under reductive or oxidative conditions, and/or contact-lithography

Within the present disclosure, a substrate is configured to allow fabrication for controlled total area of super low-stress silicon nitride on doped silicon that contain electron transparent ‘windows’ of free-standing SiNₓ periodically throughout the chip. In illustrative embodiments, the substrates may be configured for a total area within the range of about 1 cm² to about 300 cm² of super low-stress silicon nitride on doped silicon that contain electron transparent ‘windows’ of free-standing SiNₓ periodically throughout the chip. The geometry of these chips can be highly important, as the fabrication of combinatorial materials libraries is typically only possible on cm-scale substrates.

Besides bare SiNₓ, many other thin films can be used as free-standing membranes, either instead of, or in addition to, the SiNₓ film. These films may include metal oxide films such as ITO Al₂O₃, TiO₂, Ta₂O₅, Mo₂O₃, SiO₂. ZnO or HfO₂; metallic films such as Au, Pt, Ti, Cr, W; semiconducting films such as GaAs, or InP; or other films such as SiC, glassy carbon, or graphene.

In a typical fabrication process for electron transparent substrates, an Si wafer begins with about 300-375 μm thickness, with 50 nm super low-stress LPCVD SiNₓ films on both sides. However, in some embodiments, the starting thicknesses of both the wafer and membrane material can be adjusted within a wide range. In some embodiments, the concentration of dopant of the wafers can be selected, which can affect, among other things, the conductivity and etch rate in KOH.

The wafer can be etched on the backside using photolithography, dry etching to remove exposed SiNₓ. Wet etching can create areas of free-standing SiNₓ on the top side with all Si etched from the backside (e.g., underneath). The entire wafer is generally submerged, for example, with in KOH during the etching process; however, areas protected by SiNₓ will not be etched during the wet etch. As dry etching can remove the SiNₓ film in the exposed areas on the backside of the wafer, the Si that is now exposed on the backside is etched in KOH, as it is no longer shielded by the SiNₓ film.

The SiNₓ window size and inter-window pitch can be tuned, for example, by either changing the photomask design and/or by incorporating deep reactive ion etching (DRIE) prior to wet etching. The window size can be implemented to be as small as a few μm square and as large as tens or hundreds μm square depending on the membrane material and thickness. In some embodiments, the average area of the thin-film windows range from about 0.04 to about 250,000 μm², and preferably from about 400 to about 22,500 μm², and more preferably from about 2,500 to about 10,000 μm². Tuning window thickness, size, and spacing can be important for increasing (e.g., maximizing) electron transparency percentage of the overall substrate, thereby increasing (e.g., maximizing) the area of the micro-/nanoentities, e.g., nanomaterials, that can be characterized via EM while balancing with the stability. While greater number of smaller windows can lead to higher structural stability, it can result in a smaller overall electron-transparent area compared to fewer, larger windows.

The thickness of the SiNₓ can be tuned by performing a reactive plasma etch with CF₄/O₂ on the top side of the wafer, selectively thinning the 50 nm SiNₓ film to the desired thickness. In some embodiments, the thickness of the thin film windows range on average from about 1 to about 100 nm, and more preferably from about 2 to about 50 nm, and preferably from about 4 to about 30 nm, and more preferably from about 5 to about 20 nm, and even more preferably from about 5 to about 15 nm. To tune the geometry of the substrate to fit the needs of the materials library synthesis, additional areas of the wafer can be etched during the process to create ‘trenches,’ or areas of the chip that have thinned or no Si, allowing for easy cleavage (e.g., breaking apart). For example, if starting with a 4-inch wafer, but the desired substrate size is 2 cm×2 cm, trenches can be etched around 4 cm² squares within the larger 4-inch wafer in addition to the windows, allowing for the wafer to be easily cleaved into substrates of the appropriate size.

To create sub-samples that can be loaded into geometry-constrained instruments, such as a TEM, additional trenches can be added to allow subsequent cleavage into 5 mm×4 mm rectangles, for example, or to appropriate geometry to fit the desired characterization equipment.

If multiple sets of trenches are required, for example if the wafer needs to be diced into substrates, and substrates need to be further diced into subsamples, the mechanical stability of each respective set of trenches can be tuned by changing the size or depth of the trench. For example, the trenches used to subdivide into substrates can be wider, making dicing into substrates easier, while the trenches used to subdivide into sub-samples (for TEM, for example) can be made thinner, meaning the substrate is more mechanically stable. The mechanical stability of the trenches and/or windows can be tuned by changing the dimensions of trenches, the thickness of the base wafer, and/or the thickness of SiNₓ and/or the size of the transparent windows.

After lithography and etching, and either before or after dicing, these substrates can be modified in a number of different ways, including atomic layer deposition of thin films, chemical vapor deposition of surface modifiers, spin-coated with various polymeric or molecular thin films, transfer of two-dimensional materials such as graphene, among others. If the substrates need to be conductive around the edges of said substrate, metals, such as gold, titanium, or chromium, can be deposited via e-beam evaporation or sputtering. This process can also enable the labeling of substrates with identifiers such as serial numbers. In some embodiments, after such surface modification, the nitride film may be removed in its entirety by performing the reactive plasma etch with CF₄/O₂ from the backside through the full thickness of the SiNₓ film.

FIG. 1 is a schematic illustration of exemplary processing steps to prepare an exemplary substrate. Starting in the upper left hand corner, the exemplary process starts with a base wafer (such as Si, grey) with thin films (such as SiNx, brown) on both sides, labelled as “Base Wafer: SiNx/Si”. The side view shows a cross sectional view of one portion of the wafer. In an exemplary fabrication process, the Si wafer begins with about 350 μm thickness, with super low-stress LPCVD SiNx films having a thickness of about 50 nm on both sides. The top view shows the SiNx film on the frontside.

A photoresist (“PR”), shown in red, is deposited on one side of the wafer (shown on the top of the wafer and now referred to as the “frontside”). Photolithography is then performed on the front side to expose a desired pattern. This may include stripes, frames, and labels, among others. The top view shows an exemplary pattern.

A film, such as Ti, Cr, and/or Au (shown in yellow), can be next deposited on the frontside of the wafer. As shown in the bottom figure in the left column, the photoresist, including the areas of the film that have photoresist underneath them, is then lifted off in a solvent such as acetone, leaving behind the pattern of the film that was defined by photolithography.

Following this, the backside of the wafer can be processed. As shown in the bottom figure of the middle column, photoresist is deposited on the backside of the wafer. Moving up the figure, the next box shows photolithography performed to expose a desired pattern on the backside. This may include stripes and squares, among others. This pattern defines the geometry of the resulting substrates, and must be sized according to the dimensions of the base wafer. For example, squares or rectangles can result in electron-transparent windows on the other side only if they are large enough to allow for subsequent etching of the full thickness of the wafer. Similarly, lines can form cleavage points in the substrates only if they are wide enough to allow for etching through parts of the Si wafer, but not so wide as to etch through its entirety.

After photolithography on the backside, a dry etch is performed to remove the thin film (e.g., SiNx) on the backside of the wafer where it is not effectively masked by the photoresist to expose the base wafer underneath. The remaining photoresist can be then stripped away. As shown by the top two figures in the middle column, the geometry and spacing of the remaining points of thin film on the bottom side will dictate the size of the windows and the placement of cleavage lines for the trenches.

As shown in the top box in the middle column of FIG. 1, a wet etch is then performed such that all areas that have the base wafer material exposed is etched away. As shown in the figure, the portions with narrow gaps between the points of the backside's remaining thin film will only etch away a portion of the Si wafer, thereby leaving trenches as cleavage points. In contrast, the portions with sufficient gaps between the points of the backside's remaining thin film will etch completely through to the thin film of the frontside to create window locations. The thin film on the frontside of the wafer acts as an etch mask and protect the parts of the wafer on the frontside from being etched.

As shown by the top box in the third column, when the pattern on the backside of the wafer is designed appropriately, the full thickness of the wafer can be etched away in some areas. The dry etch further thins the frontside's thin film, leaving behind electron-transparent “windows” consisting of only the frontside's thin film material.

In addition, thinner exposed areas such as lines and stripes can result in partially etched “trenches” that serve as cleavage sites for breaking substrates into smaller pieces. The wet etch can be fully or partially replaced by a deep dry etch. For example, following the wet etching, another dry etch can be performed to reduce the final thickness of the electron-transparent windows for particular applications. The wafer can be cleaved along trenches generated during the wet etching process to yield substrates of defined geometries.

Wafer cleavage can be performed at any point in the process after the wet etching step. It can also be done iteratively, for example, the full wafer may be cleaved initially into 2×2 cm substrates which are subjected to further processing steps before being further cleaved into smaller substrates. Further (optional) processing may include nanolithography and thermal treatment to deposit nanoparticle arrays on larger (e.g. 2×2 cm) substrates. These nanoparticle arrays can be characterized by techniques such as AFM and SEM. For high-resolution characterization, these substrates may be further cleaved into 5×4 mm substrates that can be characterized by techniques such as(S)TEM.

Optional processing may include the fabrication of nanoparticle megalibraries on the electron-transparent substrates. They may be then characterized on the substrates as-fabricated and/or the substrates may be cleaved further into sub-chips to enable high-resolution characterization by techniques such as(S)TEM.

In some embodiments, thin films other than SiNₓ may be used directly on the base silicon wafer. For example, a SiC film may be grown onto the wafer instead of SiNₓ, resulting in chips with bare SiC windows at the end. In some embodiments, base wafers other than silicon can be used. For example, a GaAs wafer could be used with a SiO₂ film in a dry etching process.

In some embodiments, backside processing can also be performed before or without frontside processing. The backside processing is required to create the windows.

In some embodiments, the substrate edge lengths range from about 0.3 to about 15 cm. In some embodiments, the substrate edge lengths range from about 0.5 and about 3.0 cm, and more preferably from about 0.5 to about 2.5 cm, and about 4 cm² squares in some particular embodiments.

In some embodiments, the sub-substrate edge lengths range from about 0.2 to about 15 cm. In some embodiments, the sub-substrate edge lengths range from about 0.2 to about 3.0 cm, and more preferably from about 2 mm to about 10 mm, and about 5×4 mm rectangles in some particular embodiments. In some embodiments, the sub-substrates may have the same size and may be evenly spaced, but in some embodiments, may have various different sizes from each other and/or be spaced with the same or different distances from each other.

In some embodiments, the number of sub-substrates in the larger substrate is within the range from about 0 to about 1500. In some embodiments, the number of sub-substrates in each larger substrate is within the range from about 5 to about 500, and preferably from about 5 to about 100, and more preferably from about 10 to about 30.

In some embodiments, the electron transparent windows may have at least one minimum dimension within the range of about 1 to about 200 μm in the plane of the wafer. In some embodiments, the electron transparent windows have at least one minimum dimension of within the range from about 0.01 to about 500 μm, and preferably from about 10 to about 200 μm, and more preferably from about 50 to about 100 μm.

In some embodiments, the electron transparent windows may be periodic (i.e., three or more windows spaced apart from adjacent windows by the same distance) in the plane of the wafer and are spaced by a distance within the range from about 1 to about 10000 μm in the plane of the wafer. In some embodiments, the electron transparent windows may be spaced in the plane of the window by a distance within the range from about 100 to about 2000 μm, and preferably from about 200 to about 1000 μm, and more preferably from about 300 to about 600 μm.

In some embodiments, the base wafer is within the range from about 50 to about 3000 μm thick. In some embodiments, the thickness of the base wafer within the range from about 50 to about 1000 μm, and preferably from about 100 to about 500 μm, and more preferably from about 300 to about 400 μm.

In some embodiments, the beginning thickness for the thin films is within the range from about 1 to about 1000 nm thick. In some embodiments, the beginning thickness of the thin films is within the range from about 30 to about 200 nm, and more preferably from about 40 to about 100 nm, and even more preferably from about 45 to about 65 nm.

In some embodiments, the number of windows per 1 cm² of substrate is within the range of about 0.1 to about 400. In some embodiments, the number of windows per 1 cm² of substrate is within the range from about 0.5 to about 100, and preferably from about 1 to about 20, and more preferably from about 2 to about 5.

FIG. 2 shows an example of substrate fabrication. FIG. 2A shows the design for photolithography for the frontside of a wafer. The design shows the areas for thirteen substrates that are each 2 cm by 2 cm. FIG. 2B shows the wafer after frontside processing. The callout shows the lines between areas for 2 cm by 2 cm substrates. FIG. 2C shows the design for backside photolithography and FIG. 2D shows the backside of the wafer after dry etching. The callout for FIG. 2D shows the trench lines for areas that can be cleaved into 20 smaller substrates (also referred to as “chips”). FIG. 2E shows four 2 cm by 2 cm substrates produced from the larger wafer. FIG. 2F shows one 2 cm by 2 cm substrate that is further cleaved into twenty 5×4 mm chips. Each of the 5×4 mm chips contains 42 windows. Thus, the 2 cm×2 cm substrate of this example includes 840 windows, or 210 windows per 1 cm².

In the example of FIG. 2, a 100 mm P/B (100) 375±25 μm prime grade silicon wafer with 500 Å±5% super low stress LPCVD silicon nitride on both sides with a film stress≤100 MPa±55 MPa tensile stress is used as the base wafer. An adhesion promoter is spin coated on one side of the wafer, followed by spin coating that side with a photoresist which is then cured on a hotplate. After that, photolithography is performed on a maskless aligner, and the pattern is developed. The wafer is then treated with 30W O₂ plasma for 2 minutes. The wafer is loaded into an e-beam evaporator, and a Cr/Au film is deposited on the surface. The photoresist is then lifted off in an acetone bath. Then, an adhesion promoter is spin coated onto both sides of the wafer. Photoresist is spin coated on both sides of the wafer and cured in a convection oven. Photolithography is performed in a maskless aligner on the side that does not have the Au pattern, and the pattern is developed. A reactive ion etch is performed on the side that does not have the gold pattern using 200W 14% O₂/CF₄ plasma for 75 s, and the residual photoresist is removed in an acetone bath. A wet etch is performed in 30% KOH at 70° C. to etch through the entire wafer. The resulting windows are thinned by a reactive ion etch using 200W 14% O₂/CF₄ plasma for 22 s, resulting in ˜15 nm thick windows. The wafer is then cleaved into 13 2×2 cm substrates along one set of etched trenches. For high-resolution characterization, each of these 2×2 cm substrates is cleaved along a second set of trenches into 5×4 mm chips at a later time.

FIG. 1: Schematic illustration of the processing (not to scale).

FIG. 2: Example of substrate fabrication. (A) Design for front side photolithography; (B) Wafer after frontside processing; (C) Design for backside photolithography; (D) Wafer after backside dry etching; (E) 4 substrates produced from the larger wafer; (F) One substrate cleaved into 20 5×4 mm chips.

Accordingly, the various embodiments of the invention, as disclosed above, are intended to be illustrative, not limiting. Various changes may be made without departing from the spirit and scope of the invention. As a result, it will be apparent for those skilled in the art that the illustrative embodiments described are only examples and that various modifications can be made within the scope of the invention as defined in the appended claims.

1. A method for preparing electron transparent substrate, the method comprising:
providing a base wafer having a bulk core, a first thin film layer disposed on one side of the bulk core corresponding with a frontside of the base wafer, and a second thin film layer disposed on an opposite side of the bulk core corresponding with a backside of the base wafer;
subjecting the base wafer, on the backside, to (i) photolithography to define removal regions, and to (ii) etching to remove portions of the second thin film layer corresponding to the defined removal regions to allow exposure of bulk core via the backside of the base wafer; and
subjecting the base wafer, on the backside, to wet etching to remove portions of the bulk core, wherein removed portions of the bulk core include thickened portions of the bulk core extending through the bulk core to the first thin film layer to expose portions of the first thin film layer via the backside to define electron transparent windows, and trench portions extending partially into the bulk core from the backside to define trenches for sectioning of the base wafer.

2. The method of claim 1, further comprising subjecting the base wafer to dry etching for thickness reduction of the first thin film layer.

3. The method of claim 2, wherein subjecting the base wafer to dry etching for thickness reduction of the first thin film layer comprises thickness reduction of the first thin film layer in regions including the electron transport windows.

4. The method of claim 2, wherein subjecting the base wafer to dry etching comprises reactive plasma etching.

5. The method of claim 1, wherein subjecting the base wafer to wet etching to remove trench portions comprises partially removing portion of the bulk core as the trench portions such that the defined trenches do not extend entirely through the bulk core to the first thin film layer.

6. The method of claim 5, further comprising cleaving the wafer into samples according to sectioning as defined by the trenches.

7. The method of claim 6, wherein sectioning includes sample sectioning the base wafer into sample sections and sub-sectioning the sample sections into sub-sample sections, and cleaving includes cleaving the base wafer into samples according to the sample sections and sub-cleaving the samples into sub-samples according to the sub-sample sections.

8. The method of claim 7, further comprising determining mechanical stability parameters for sectioning based on determined mechanical stability needs.

9. The method of claim 8, wherein sectioning based on the determined mechanical stability needs includes defining trench dimensions for samples as greater than trench dimensions for sub-samples.

10. The method of claim 1, further comprising modifying the base wafer.

11. The method of claim 10, wherein modifying the base wafer includes one or more of atomic layer deposition of thin films, chemical vapor deposition of surface modifiers, spin-coating with polymeric or thin films.

12. The method of claim 11, wherein modifying the base wafer includes depositing conductive material near substrate edges.

13. The method of claim 11, wherein modifying is performed before subjecting the base wafer, on the backside, to photolithography.

14. The method of claim 11, wherein modifying is performed after subjecting the base wafer, on the backside, to photolithography, and before subjecting the base wafer, on the backside, to wet etching.

15. The method of claim 1, further comprising frontside processing.

16. A substrate comprising a bulk core and a thin film layer deposited in part on the bulk portion, the thin film layer comprising a plurality of electron transport windows, wherein each window comprises the thin film layer material exposed on a frontside and exposed on a backside through removed portions of the bulk core, the substrate further comprises sectioning according to trenches defined by trenched portions of removed bulk core extending partially into the bulk core from the backside.

17. The substrate of claim 16, wherein the trenches define an outer perimeter of a plurality of chip areas, wherein each chip area comprises a plurality of windows and wherein the trenches are configured for cleaving to detach the chip areas from each other.

18. A wafer comprising a bulk portion and a thin film layer disposed on the bulk portion, a plurality of first trenches forming the boundaries of a plurality of substrate areas, wherein each substrate area includes a plurality of electron transparent windows defined therein, wherein each electron transparent window comprises the thin film layer accessible from opposite sides of the wafer and wherein the first trenches are configured be cleaved to form substrate samples defined by the substrate areas.

19. The wafer of claim 18, wherein an edge length of one or more of the substrate areas is within the range of 0.3 to 15 cm.

20. The wafer of claim 18, further including a plurality of second trenches, the second trenches forming the outer perimeter of a plurality of chip areas within each substrate area, wherein each chip area comprises a plurality of the electron transparent windows and wherein the second trenches are configured to be cleaved to form chips defined by the chip areas.

21. The wafer of claim 20, wherein a width of one or more of the first trenches is greater than a width of one or more of the second trenches.

22. The wafer of claim 20, wherein the plurality of chips areas includes 0 to 1500 chips areas.

23. The wafer of claim 20, wherein an edge length of at least one of the chip areas is within the range of 2 to 150 mm.

24. The wafer of claim 18, wherein the electron transparent windows have a thickness within the range of 1 to 100 nm.

25. The wafer of claim 18, wherein the electron transparent windows have at least one minimum dimension within the range of 1 to 200 μm within a longitudinal-lateral plane of the wafer.

26. The wafer of claim 18, wherein the electron transparent windows are spaced apart from each other by a distance within the range of 1 to 10000 μm within a longitudinal-lateral plane of the wafer

27. The wafer of claim 18, wherein the electron transparent windows include more than two windows each spaced apart from adjacent windows by the same distance within a longitudinal-lateral plane of the wafer.

28. The wafer of claim 18, wherein the bulk portion comprises Silicon (Si).

29. The wafer of claim 18, wherein the bulk portion is within the range of 50 to 3000 μm thick.

30. The wafer of claim 18, wherein the thin film layer comprises Silicon Nitride (SiNₓ).

31. The wafer of claim 18, wherein the thin film layer is within the range of 1 to 1000 nm thick.
